(19) United States
(12) Patent Application Publication
(10) Pub. No.: US 2021/0217649 A1
(43) Pub. Date: Jul. 15, 2021

(54) EDGE RING AND SUBSTRATE PROCESSING APPARATUS

(71) Applicant: TOKYO ELECTRON LIMITED, Tokyo (JP)

(72) Inventors: Kazuhiko AKAHANE, Miyagi (JP); Toshiya TSUKAHARA, Miyagi (JP); Sungjae LEE, Gyeonggi-do (KR); Namho YUN, Gyeonggi-do (KR); Jisoo SUH, Gyeonggi-do (KR)

(73) Assignee: TOKYO ELECTRON LIMITED, Tokyo (JP)

(21) Appl. No.: 17/145,171

(22) Filed: Jan. 8, 2021

(30) Foreign Application Priority Data
Jan. 10, 2020 (JP) 2020-002935

(51) Int. Cl. H01L 21/687; H01L 21/67; H01J 37/32

(52) U.S. Cl. CPC H01L 21/68735; H01L 21/68757; H01J 2237/3341; H01J 37/32642; H01J 37/32715; H01L 21/67069

(57) ABSTRACT

An edge ring is disposed to surround a target substrate. The edge ring includes a first upper surface made of silicon carbide, tungsten carbide, magnesium oxide, or yttria, and a second upper surface made of silicon. The second upper surface is formed at a position lower than the first upper surface to face a bottom surface of a peripheral portion of the target substrate.

### CROSS-REFERENCE TO RELATED APPLICATIONS

This application claims priority to Japanese Patent Application No. 2020-002935, filed on Jan. 10, 2020, the entire contents of which are incorporated herein by reference.

### TECHNICAL FIELD

The present disclosure relates to an edge ring and a substrate processing apparatus.

### BACKGROUND

In performing plasma processing on a substrate, an edge ring may be disposed to surround an outer circumference of a substrate disposed in a chamber maintained at a predetermined vacuum level. By disposing the edge ring, the plasma processing can be uniformly performed across the surface of the substrate.

Conventionally, an edge ring made of silicon carbide (SiC) (hereinafter, may be referred to as “SiC edge ring”) is known. Due to the high plasma resistance of the SiC edge ring, the frequency of replacement of the edge ring can be reduced (see, e.g., Japanese Patent Application Publication No. 2010-251723).

### SUMMARY

The present disclosure provides an edge ring that is replaced less frequently and capable of suppressing the generation of particles.

In accordance with an aspect of the present disclosure, there is provided an edge ring disposed to surround a substrate, including: a first upper surface made of silicon carbide, tungsten carbide, magnesium oxide, or yttria; and a second upper surface made of silicon and formed at a position lower than the first upper surface to face a bottom surface of a peripheral portion of the substrate.

### BRIEF DESCRIPTION OF THE DRAWINGS

The objects and features of the present disclosure will become apparent from the following description of embodiments, given in conjunction with the accompanying drawings, in which:

FIG. 1 shows an example of a configuration of a substrate processing apparatus according to a first embodiment;

FIG. 2 shows an example of an edge ring and a wafer according to the first embodiment;

FIG. 3 shows an example of a configuration of the edge ring according to the first embodiment;

FIG. 4 shows an example of a configuration of an edge ring according to a second embodiment; and

FIG. 5 shows an example of a configuration of an edge ring according to a third embodiment.

### DETAILED DESCRIPTION

Hereinafter, embodiments of the present disclosure will be described in detail with reference to the accompanying drawings. Like reference numerals will be given to like parts in the following embodiments.

### First Embodiment

<Configuration of Substrate Processing Apparatus>

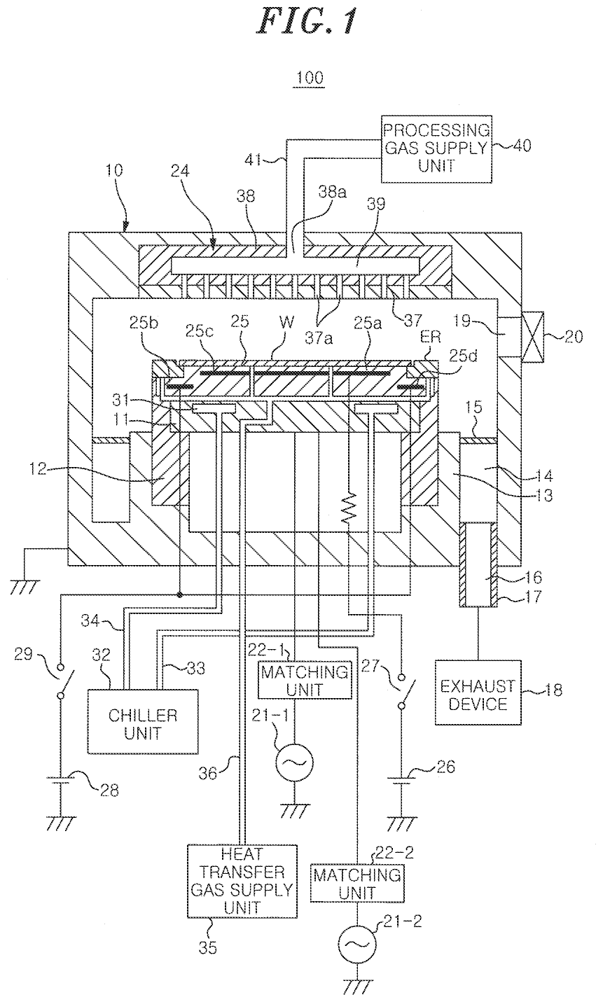

FIG. 1 shows an example of a configuration of a substrate processing apparatus according to a first embodiment.

In FIG. 1, a substrate processing apparatus 100 includes a chamber 10 that is a chamber made of a metal such as aluminum or stainless steel. The chamber 10 is frame-grounded.

A disc-shaped susceptor 11 is horizontally disposed in the chamber 10. The susceptor 11 is disposed under a bottom surface of an electrostatic chuck 25 on which a semiconductor substrate (hereinafter, may be referred to as “wafer W”) serving as a substrate and an edge ring ER are placed. Further, the susceptor 11 functions as a lower electrode to which a radio frequency (RF) power is supplied. The susceptor 11 is made of, for example, aluminum. The susceptor 11 is supported by a cylindrical support 13 that extends vertically upward from the bottom of the chamber 10 via an insulating cylindrical holder 12.

An exhaust passage 14 is formed between a sidewall of the chamber 10 and the cylindrical support 13. An annular baffle plate 15 is disposed at an entrance or in the middle of the exhaust passage 14. An exhaust port 16 is disposed at the bottom of the chamber 10. An exhaust device 18 is connected to the exhaust port 16 through an exhaust line 17. The exhaust device 18 has a vacuum pump to reduce a pressure in a processing space provided by the chamber 10 to a predetermined vacuum level. Further, the exhaust line 17 has an automatic pressure control valve (APC) that automatically controls the pressure in the chamber 10. In addition, a gate valve 20 for opening and closing a loading/unloading port 19 for the wafer W is provided to the sidewall of the chamber 10.

RF power supplies 21-1 and 21-2 are electrically coupled to the susceptor 11 through matching units 22-1 and 22-2, respectively. The RF power supply 21-1 supplies an RF power to the susceptor 11 for plasma generation. It is preferred that the RF power supply 21-1 supplies an RF power of 27 MHz to 100 MHz, for example, 40 MHz, to the susceptor 11. Further, the RF power supply 21-2 supplies an RF power to the susceptor 11 for attracting ions to the wafer W. It is preferred that the RF power supply 21-2 supplies an RF power of 400 kHz to 40 MHz, for example, 3 MHz, to the susceptor 11. The matching unit 22-1 matches an output impedance of the RF power supply 21-1 with an input impedance of the susceptor 11 side, and the matching unit 22-2 matches an output impedance of the RF power supply 21-2 with the input impedance of the susceptor 11 side.

A shower head 24 serving as an upper electrode having a ground potential is disposed at a ceiling of the chamber 10.

The electrostatic chuck 25 disposed on an upper surface of the susceptor 11 attracts and holds the wafer W and the edge ring ER placed on the electrostatic chuck 25 by an electrostatic attractive force. The electrostatic chuck has a disc-shaped central portion 25a and an annular outer peripheral portion 25b. The central portion 25a projects upward with respect to the outer peripheral portion 25b. The wafer W is placed on an upper surface of the central portion 25a, and the edge ring ER is placed on an upper surface of the outer peripheral portion 25b to annularly surround the central portion 25a. The central portion 25a is formed by interposing an electrode plate 25c made of a conductive film between a pair of dielectric films. The outer peripheral portion 25b is formed by interposing an electrode plate 25d made of a conductive film between a pair of dielectric films. In other words, the electrode plates 25c and 25d are disposed in the electrostatic chuck 25. Further, the electrode plate 25c is disposed in a region of the electrostatic chuck 25a to correspond to the wafer W, and the electrode plate 25d is disposed in a region of the electrostatic chuck 25 to correspond to the edge ring ER. A DC power supply 26 is electrically connected to the electrode plate 25c through a switch 27. A DC power supply is electrically connected to the electrode plate 25d through a switch 29. The electrostatic chuck 25 attracts and holds the wafer W by the Coulomb force or the Johnson-Rahbek force generated by a DC voltage applied from the DC power supply 26. Further, the electrostatic chuck 25 attracts and holds the edge ring ER by the Coulomb force or the Johnson-Rahbek force generated by a DC voltage applied from the DC power supply 28. In other words, when FIG. 1 is viewed in plan view, the electrode 25c for electrostatically attracting and holding the wafer W is disposed at an inner region of the electrostatic chuck 25 such that the electrode 25c overlaps with at least a part of the wafer W, and the electrode 25d for electrostatically attracting and holding the edge ring ER is disposed at an inner region of the electrostatic chuck 25 such that the electrode 25d overlaps with at least a part of the edge ring ER.

As described above, the wafer W is placed on the upper surface of the central portion 25a of the electrostatic chuck 25, and the edge ring ER is placed on the upper surface of the outer peripheral portion 25b of the electrostatic chuck 25 to annularly surround the central portion 25a. In other words, the edge ring ER is disposed on the electrostatic chuck 25 to surround the outer circumference of the wafer W. Further, the bottom surface of the electrostatic chuck 25 and the upper surface of the susceptor 11 are in contact with each other. Therefore, the susceptor 11 and the electrostatic chuck 25 serve as a substrate support on which the wafer W and the edge ring ER are placed.

An annular cooling medium space 31 extending in a circumferential direction is disposed in the susceptor 11. A cooling medium (e.g., cooling water) having a predetermined temperature is supplied from a chiller unit 32 and circulated in the cooling medium space 31 through lines 33 and 34, and a processing temperature of the wafer W on the electrostatic chuck 25 is controlled by a temperature of the cooling medium. Further, a heat transfer gas (e.g. He gas) is supplied from a heat transfer gas supply unit 35 to a space between the upper surface of the electrostatic chuck 25 and a bottom surface of the wafer W and to a space between the upper surface of the electrostatic chuck 25 and a bottom surface of the edge ring ER through a gas supply line 36. The heat transfer gas supplied from the heat transfer gas supply unit 35 through the gas supply line 36 enhances the heat transfer between the wafer W and the electrostatic chuck 25 and the heat transfer between the edge ring ER and the electrostatic chuck 25.

The shower head 24 disposed at the ceiling has an electrode plate 37 having multiple gas injection holes 37a and an electrode holder 38 for holding the electrode plate 37. Further, a buffer space 39 is formed in the electrode holder 38, and a gas supply line 41 from a processing gas supply unit 40 is connected to a gas inlet port 38a of the buffer space 39.

When the substrate processing apparatus 100 performs, for example, dry etching, first, the gate valve 20 is opened, and the wafer W is loaded into the chamber 10 and placed on the electrostatic chuck 25. Then, a gas mixture containing C₄F₈ gas, O₂ gas and Ar gas with a predetermined flow ratio is introduced into the chamber 10 as a processing gas from the processing gas supply unit 40. The pressure in the chamber 10 is set to a predetermined level by the exhaust device 18. Then, the switches 27 and 29 are turned on to apply a DC voltage from the DC power supply 26 to the electrode plate 25c and to apply a DC voltage from the DC power supply 28 to the electrode plate 25d. Accordingly, the wafer W and the edge ring ER are electrostatically attracted and held on the electrostatic chuck 25. Then, an RF power is supplied to the susceptor 11 from the RF power supplies 21-1 and 21-2. Accordingly, the processing gas injected through the shower head 24 is turned into plasma, and the surface of the wafer W is etched by radicals or ions contained in the plasma.

<Edge Ring and Wafer>

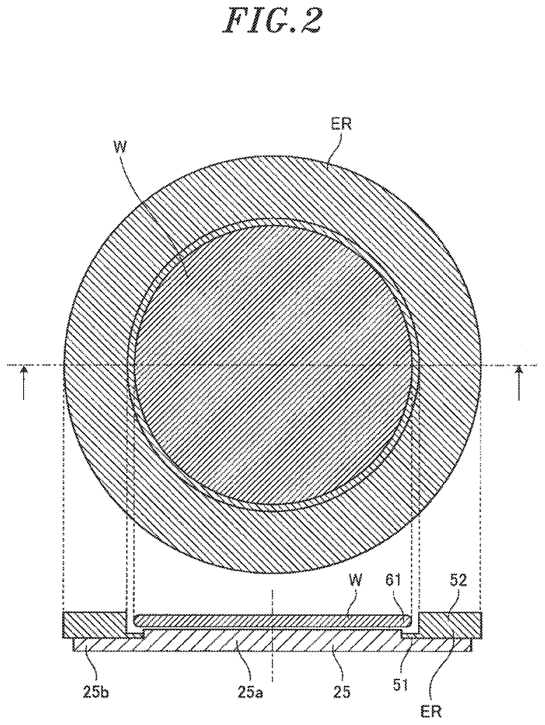

FIG. 2 shows examples of the edge ring and the wafer according to the first embodiment.

As shown in FIG. 2, the edge ring ER has an annular shape, and an inner peripheral portion 51 of the edge ring ER is formed to be thinner than an outer peripheral portion of the edge ring ER. In this example, the outer peripheral portion 25b of the electrostatic chuck 25 is formed to be thinner than the central portion 25a of the electrostatic chuck 25. The edge ring ER is placed on the outer peripheral portion 25b of the electrostatic chuck 25, and the wafer W is placed on the central portion 25a of the electrostatic chuck 25. Further, in this example, the inner peripheral portion 51 of the edge ring ER is formed such that an upper surface of the inner peripheral portion 51 of the edge ring ER is lower than an upper surface of the central portion 25a of the electrostatic chuck 25. Further, in this example, the outer peripheral portion 52 of the edge ring ER is formed such that an upper surface of the outer peripheral portion 52 of the edge ring ER has substantially the same height as the upper surface of the wafer W or is higher than the upper surface of the wafer W. In addition, the wafer W has a disc shape, and a diameter of the wafer W is greater than a diameter of the central portion 25a of the electrostatic chuck 25. Therefore, when the wafer W is placed on the central portion 25a of the electrostatic chuck 25, a bottom surface of a peripheral portion 61 of the wafer W and the upper surface of the inner peripheral portion 51 of the edge ring ER face each other.

<Configuration of Edge Ring>

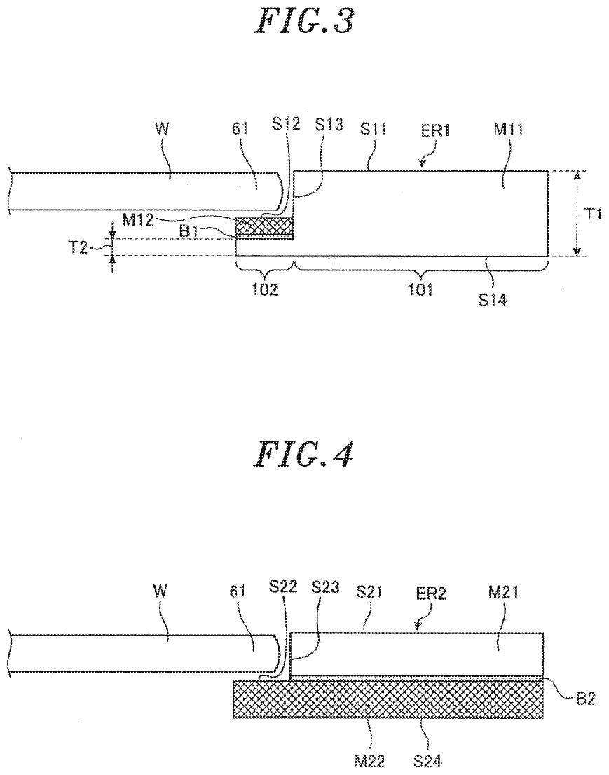

FIG. 3 shows an example of a configuration of the edge ring according to the first embodiment. An edge ring ER1 shown in FIG. 3 corresponds to the edge ring ER shown in FIGS. 1 and 2.

In FIG. 3, the edge ring ER1 is formed by joining a member M11 and a member M12 via an adhesive layer B1. The member M11 is made of, for example, silicon carbide, tungsten carbide (WC), magnesium oxide (MgO), or yttria (Y₂O₃), and the member M12 is made of, for example, silicon. The member M11 has an upper surface S11, a side surface S13, and a bottom surface S14. The member M12 has an upper surface S12. Further, the member M11 has an outer peripheral portion 101 and an inner peripheral portion 102, and the outer peripheral portion 101 includes the upper surface S11. In the member M11, a thickness T2 of the inner peripheral portion 102 is smaller than a thickness T1 of the outer peripheral portion 101. The member M12 is disposed on the inner peripheral portion 102 of the member M11. The adhesive layer B1 contains, for example, a silicone-based adhesive. The adhesive layer B1 may further contain a conductive filler.

Therefore, the edge ring ER1 has the upper surface S11 made of silicon carbide, tungsten carbide, magnesium oxide, or yttria, and the upper surface S12 made of silicon. Further, the upper surface S12 is formed at a position lower than the upper surface S11, and the upper surface S12 faces the bottom surface of the peripheral portion 61 of the wafer W. Further, the edge ring ER1 has the side surface S13 made of silicon carbide, tungsten carbide, magnesium oxide, or yttria, and the side surface S13 connects the end of the upper surface S11 and the end of the upper surface S12. The edge ring ER1 has the bottom surface S14 made of silicon carbide, tungsten carbide, magnesium oxide, or yttria, and the bottom surface S14 is opposite to the upper surface S11 and the upper surface S12.

### Second Embodiment

<Configuration of Edge Ring>

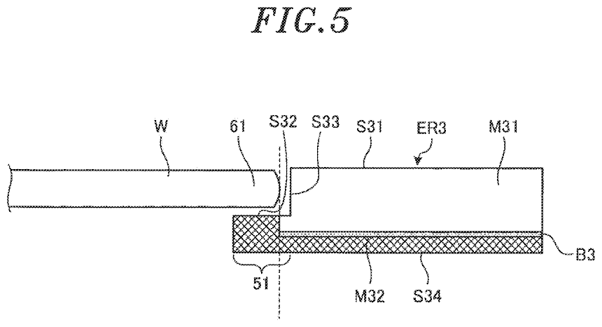

FIG. 4 shows an example of a configuration of an edge ring according to a second embodiment. An edge ring ER2 shown in FIG. 4 corresponds to the edge ring ER shown in FIGS. 1 and 2.

In FIG. 4, the edge ring ER2 is formed by joining a member M21 and a member M22 via an adhesive layer B2. The member M21 is made of, for example, silicon carbide, tungsten carbide, magnesium oxide, or yttria and the member M22 is made of, for example, silicon. The member M22 is disposed below the member M21. The member M21 has an upper surface S21 and a side surface S23, and the member M22 has an upper surface S22 and a bottom surface S24. The adhesive layer B2 contains a silicone-based adhesive. The adhesive layer B2 may further contain a conductive filler. The upper surface S22 corresponds to the upper surface of the inner peripheral portion 51 of the edge ring ER.

Therefore, the edge ring ER2 has the upper surface S21 made of silicon carbide, tungsten carbide, magnesium oxide, or yttria, and the upper surface S22 made of silicon. Further, the upper surface S22 is formed at a position lower than the upper surface S21, and the upper surface S22 faces the bottom surface of the peripheral portion 61 of the wafer W. Further, the edge ring ER2 has the side surface S23 made of silicon carbide, tungsten carbide, magnesium oxide, or yttria, and the side surface S23 connects the end of the upper surface S21 and the end of the upper surface S22. Further, the edge ring ER2 has the bottom surface S24 made of silicon, and the bottom surface S24 is opposite to the upper surface S21 and the upper surface S22.

Since the bottom surface S24 in contact with the upper surface of the outer peripheral portion 25b of the electrostatic chuck 25 is made of silicon that is more flexible than silicon carbide, tungsten carbide, magnesium oxide, and yttria, the adhesion between the electrostatic chuck 25 and the edge ring ER2 is improved.

### Third Embodiment

<Configuration of Edge Ring>

FIG. 5 shows an example of a configuration of an edge ring according to a third embodiment. An edge ring ER3 shown in FIG. 5 corresponds to the edge ring ER shown in FIGS. 1 and 2.

In FIG. 5, the edge ring ER3 is formed by joining a member M31 and a member M32 via an adhesive layer B3. The member M31 is made of, for example, silicon carbide, tungsten carbide, magnesium oxide, or yttria and the member M32 is made of, for example, silicon. The member M31 has an upper surface S31 and a side surface S33, and the member M32 has an upper surface S32 and a bottom surface S34. The adhesive layer B3 contains a silicone-based adhesive. The adhesive layer B3 may further contain a conductive filler.

Therefore, the edge ring ER3 has the upper surface S31 made of silicon carbide, tungsten carbide, magnesium oxide, or yttria, and the upper surface S32 made of silicon. Further, the upper surface S32 is formed at a position lower than the upper surface S31, and the upper surface S32 faces the bottom surface of the peripheral portion 61 of the wafer W. Further, the edge ring ER3 has the side surface S33 made of silicon carbide, tungsten carbide, magnesium oxide, or yttria. Further, the edge ring ER3 has the bottom surface S34 made of silicon, and the bottom surface S34 is opposite to the upper surface S31 and the upper surface S32.

Since the bottom surface S34 in contact with the upper surface of the outer peripheral portion 25b of the electrostatic chuck 25 is made of silicon that is more flexible than silicon carbide, tungsten carbide, magnesium oxide, and yttria, the adhesion between the electrostatic chuck 25 and the edge ring ER3 is improved.

In the example of the configuration shown in FIG. 5, at least a portion of the inner peripheral portion 51 of the edge ring ER that does not face the bottom surface of the peripheral portion 61 of the wafer W is made of silicon carbide, tungsten carbide, magnesium oxide, or yttria. Since the portion of the edge ring ER that does not face the bottom surface of the peripheral portion 61 of the wafer W is made of silicon carbide, tungsten carbide, magnesium oxide, or yttria, it is possible to further suppress the consumption of the edge ring due to the plasma processing and also possible to avoid direct contact between the adhesive layer and the plasma.

As described above, the edge ring (the edge rings ER1, ER2, and ER3) according to the embodiments of the present disclosure includes a first upper surface (the upper surfaces S11, S21, and S31) made of silicon carbide, tungsten carbide, magnesium oxide, or yttria, and a second upper surface (the upper surfaces S12, S22, and S32) that is made of silicon and formed at a position lower than the first upper surface so as to face the bottom surface of the peripheral portion of the wafer W.

Since the first upper surface exposed to the plasma by the plasma processing is made of plasma-resistant silicon carbide, tungsten carbide, magnesium oxide, or yttria, the consumption of the edge ring due to the plasma processing can be suppressed. Further, since the second upper surface facing the bottom surface of the peripheral portion of the wafer W is made of silicon, reaction products of silicon with the plasma do not become particles. Therefore, the particle generation at the outer peripheral portion of the wafer W can be suppressed. Accordingly, when the edge ring according to the embodiments of the present disclosure is used for the plasma processing, it is possible to reduce the frequency of replacement of the edge ring and suppress the particle generation.

Although the edge ring and the substrate processing apparatus according to the embodiments of the present disclosure have been described, the edge ring and the substrate processing apparatus of the present disclosure are not limited to those in the above-described embodiments, and various modifications and improvements can be made within the scope of the present disclosure. The above-described embodiments can be combined without contradicting processing contents thereof.

For example, the edge ring of the present disclosure can be applied not only to a capacitively coupled plasma (CCP) processing apparatus but also to other substrate processing apparatuses. The other substrate processing apparatuses may include an inductively coupled plasma (ICP) processing apparatus, a plasma processing apparatus using a radial line slot antenna, a helicon wave plasma (HWP) processing apparatus, and an electron cyclotron resonance plasma (ECR) processing apparatus.

Although the semiconductor substrate has been described as a plasma processing target in the specification, the plasma processing target is not limited to the semiconductor substrate. The plasma processing target may include various substrates used for liquid crystal display (LCD) or flat panel display (FPD), a photomask, a CD substrate, and a printed circuit board.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. An edge ring disposed to surround a substrate, comprising:
a first upper surface made of silicon carbide, tungsten carbide, magnesium oxide, or yttria; and
a second upper surface made of silicon and formed at a position lower than the first upper surface to face a bottom surface of a peripheral portion of the substrate.

2. The edge ring of claim 1, further comprising:
a bottom surface opposite to the first upper surface and the second upper surface, and made of silicon carbide, tungsten carbide, magnesium oxide, or yttria.

3. The edge ring of claim 1, further comprising:
a bottom surface opposite to the first upper surface and the second upper surface, and made of silicon.

4. The edge ring of claim 1, wherein the edge ring is formed by joining a first member having the first upper surface and a second member having the second upper surface.

5. The edge ring of claim 4, wherein the first member and the second member are joined via an adhesive layer.

6. The edge ring of claim 5, wherein the adhesive layer contains a silicone-based adhesive.

7. The edge ring of claim 6, wherein the adhesive layer further contains a conductive filler.

8. The edge ring of claim 1, further comprising:
a first member having an outer peripheral portion including the first upper surface and an inner peripheral portion having a thickness smaller than a thickness of the outer peripheral portion; and
a second member disposed on the inner peripheral portion of the first member and including the second upper surface.

9. The edge ring of claim 8, wherein the first member is made of silicon carbide, tungsten carbide, magnesium oxide, or yttria, and
the second member is made of silicon.

10. The edge ring of claim 8, wherein the first member and the second member are joined via an adhesive layer.

11. The edge ring of claim 10, wherein the adhesive layer contains a silicone-based adhesive.

12. The edge ring of claim 11, wherein the adhesive layer further contains a conductive filler.

13. The edge ring of claim 1, further comprising:
a first member including the first upper surface; and
a second member disposed below the first member and including the second upper surface.

14. The edge ring of claim 13, wherein the first member is made of silicon carbide, tungsten carbide, magnesium oxide, or yttria, and
the second member is made of silicon.

15. The edge ring of claim 13, wherein the first member and the second member are joined via an adhesive layer.

16. The edge ring of claim 15, wherein the adhesive layer contains a silicone-based adhesive.

17. The edge ring of claim 16, wherein the adhesive layer further contains a conductive filler.

18. A plasma processing apparatus comprising:
a chamber that provides a processing space;
a support disposed in the chamber and on which a substrate is placed; and
an edge ring disposed to surround the substrate,
wherein the support includes an electrode that electrostatically attracts and holds the edge ring in a region that overlaps with at least a part of the edge ring in plan view, and
the edge ring includes:
a first upper surface made of silicon carbide, tungsten carbide, magnesium oxide, or yttria; and
a second upper surface made of silicon and formed at a position lower than the first upper surface to face a bottom surface of a peripheral portion of the substrate.

19. The edge ring of claim 9, wherein the first member and the second member are joined via an adhesive layer.

20. The edge ring of claim 14, wherein the first member and the second member are joined via an adhesive layer.
